(19) United States
(12) Patent Application Publication
(10) Pub. No.: US 2011/0064235 A1
(43) Pub. Date: Mar. 17, 2011

(54) MICROPHONE AND AUDIO SIGNAL PROCESSING METHOD

(76) Inventor: Jake Allston, Burbank, CA (US)

(21) Appl. No.: 12/881,922

(22) Filed: Sep. 14, 2010

Related U.S. Application Data
(60) Provisional application No. 61/243,116, filed on Sep. 16, 2009.

(51) Int. Cl. H03G 3/00

(52) U.S. Cl. 381/63

(57) ABSTRACT

A microphone includes a housing with a user interface configured to allow selection of a voice modification. The voice modification includes at least one of distortion, delay, reverb, auto tune, pitch, and phase. An audio to electric signal converter is at least partially enclosed in the housing and is configured to convert sound vibrations into an electric voice signal. A control module is configured to generate a signal indicative of a desired sound as a function of the modification signal and the electric voice signal.

### CROSS-REFERENCE TO RELATED APPLICATION

This application claims the benefit of the filing date under 35 USC 119(e) of the filing date of U.S. Provisional Application Ser. No. 61/243,116, filed Sep. 16, 2009, the contents of which are incorporated herein by reference.

### FIELD OF THE INVENTION

The field of this invention is microphones, and in particular the field is microphones with user selection interfaces.

### BACKGROUND

Microphones convert sound waves or vibrations into an electrical or electronic sound signals and transmit these signals to sound systems. When a person sings or speaks into a microphone the sound of their voice is converted into an electrical or electronic signal. This voice signal is then transmitted to the sound system. Controls on sound systems may be used to amplify and modify the voice signals and then convert them back into sounds to be listened to. For example, echoes may be added to a voice signal. If someone is singing, a pitch control may modify the voice signal to correct any errors in pitch the singer may have. Other modifications may be made to create desired effects that the individual singer or speaker could not produce themselves. Separate control modules for sound systems to modify voice signals are often expensive.

As the controls are located on the sound system, a singer or speaker is not able to modify their voice as they speak. They must depend on another person operating the sound system controls, or use modification on a recording of their voice. A singer or speaker is an artist and may want to use certain voice modifications to enhance their performance. They may want to make the modifications themselves while performing to individualize their performing style and art.

### SUMMARY OF THE INVENTION

A microphone includes a housing with a user interface configured to allow selection of a voice modification. The voice modification includes at least one of distortion, delay, reverb, auto tune, pitch, and phase. An audio to electric signal converter is at least partially enclosed in the housing and is configured to convert sound waves into an electric voice signal. A control module is configured to generate a signal indicative of a desired sound as a function of the modification signal and the electric voice signal.

An audio signal processing method includes converting sound vibrations into an electrical voice signal. A voice modification is selected on a user interface of a microphone. The voice modification includes at least one of distortion, delay, reverb, auto tune, pitch, and phase. A modification signal indicative of the voice modification is generated. A desired sound signal is then generated as a function of the electric voice signal and the modification signal.

### BRIEF DESCRIPTION OF THE DRAWINGS

The drawings, when considered in connection with the following description, are presented for the purpose of facilitating an understanding of the subject matter sought to be protected.

FIG. 1 depicts an exemplary embodiment of a microphone.

FIG. 2 depicts an exemplary embodiment of a microphone.

FIG. 3 is an exemplary block diagram of a sound system.

FIG. 4 is an exemplary block diagram of a sound system..

### DETAILED DESCRIPTION

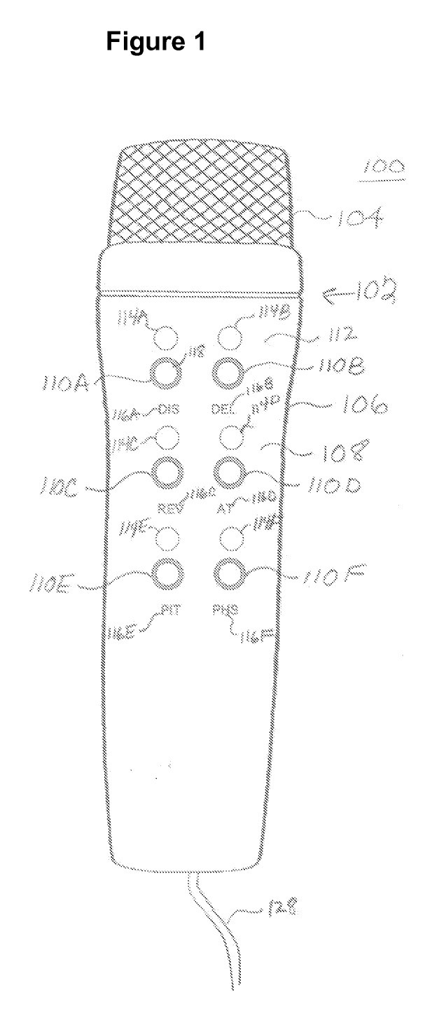

FIGS. 1-4 illustrate several embodiments of a microphone and audio signal processing method. The purpose of these figures and the related descriptions is merely to aid in explaining the principles of the invention. Thus, the figures and descriptions should not be considered as limiting the scope of the invention to the embodiments shown herein. Other embodiments of a microphone and audio signal processing method may be created which follow the principles of the invention as taught herein, and these embodiments are intended to be included within the scope of the patent.

With reference to FIG. 1, an exemplary embodiment of a microphone 100 is depicted. The microphone 100 may include any device which transforms the mechanical energy of sound waves into an analogous electrical signal known to an ordinary person skilled in the art now or in the future. For example, the microphone may include one of a carbon microphone, a dynamic microphone, a ribbon microphone, a condenser microphone, and a crystal microphone. The microphone 100 may be adapted to be held by a human hand, held in place by a stand, and/or hung by a wire or other device.

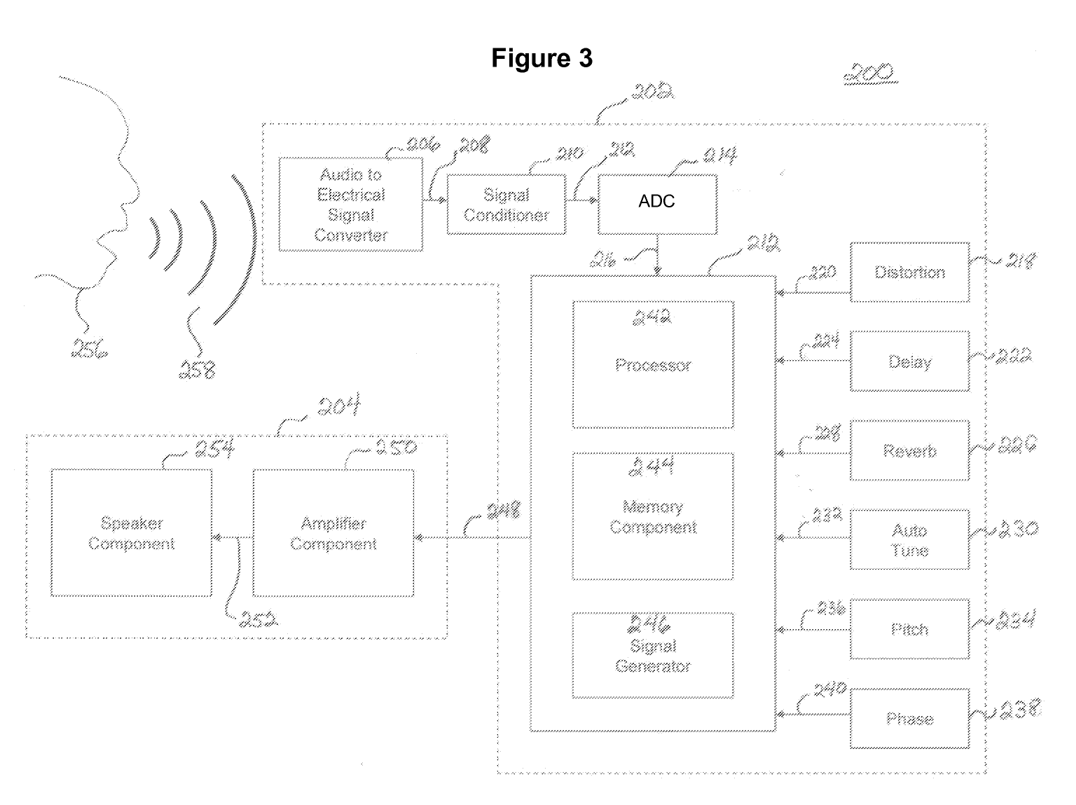

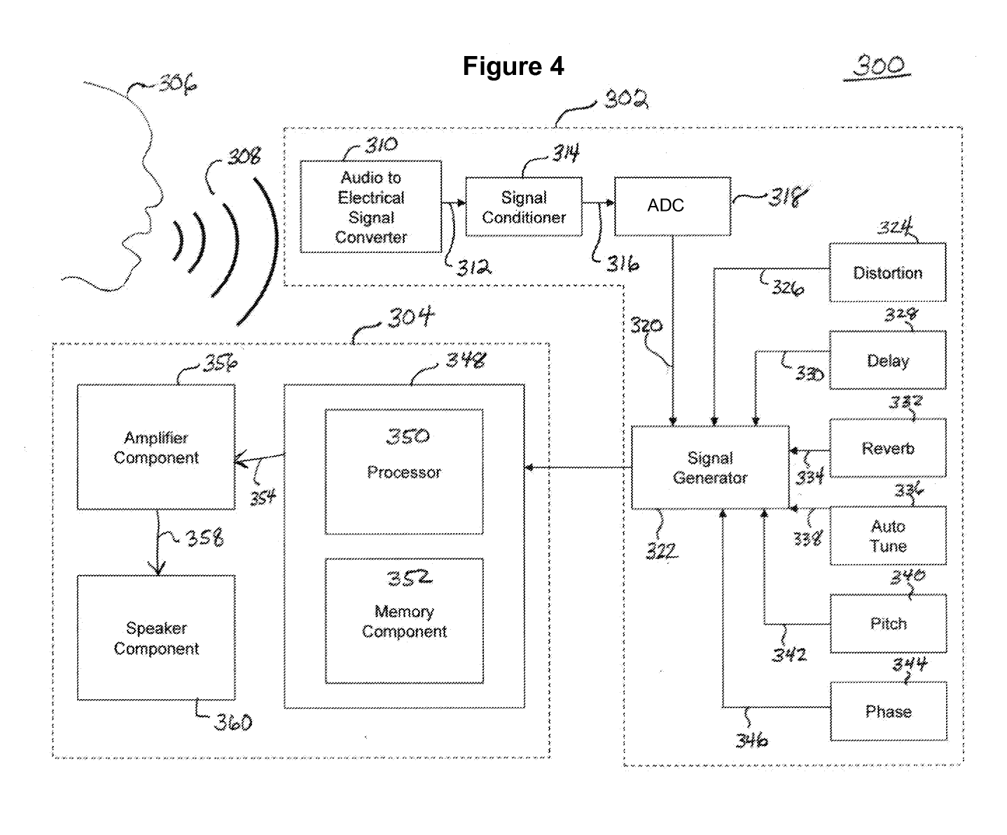

In the embodiment depicted the microphone 100 includes a housing 102. The housing 102 includes a reception portion 104 and a handle portion 106. The reception portion 104 channels sound waves to an audio to electrical converter 206 (described in relation to FIGS. 3 and 4 and hereafter referred to as an “A to E converter”). The handle portion 106 is adapted to be held in a human hand. In other embodiments the housing 102 may have other shapes and portions designed in relation to how the microphone 100 is to be used. The housing 102 may be any shape that would be known by an ordinary person skilled in the art now or in the future.

A user interface 108 is attached to the housing 102. In some embodiments the user interface 108 may be one or more separate pieces attached with glue or other adhesive, rivets, screws, or any other attachment hardware or chemical compound that would be known by an ordinary person skilled in the art now or in the future. In other embodiments the user interface 108 may be attached to the housing 102 by being integral to the housing 102. In still other embodiments the user interface 108 may be attached to the housing 102 by being at least partially enclosed by the housing 102, with portions of the user interface 108 required for the user to make selections as described below accessible. For example, portions of the user interface 108 may be accessible through apertures in the housing 102, or through sliding, latched, or hinged portions of the housing 102. In some embodiments the user interface 108 will include a plurality of elements attached to the housing 102 in different manners.

The user interface 108 allows the user of the microphone 100 to select at least one voice modification they desire. When a voice modification is selected, the voice signal 216, 320 (described below in relation to FIGS. 3 and 4) is modified to create a desired voice signal 248, 354 (described below in relation to FIGS. 3 and 4). When the desired voice signal 248, 354 is amplified and transformed into sound waves, the listener hears a voice with the user's desired modification.

There are many types of modifications used in sound systems to produce desired audio effects. The user interface 108 is configured to allow selection of a voice modification including at least one of distortion 218, 324; delay 222, 328; reverb 226, 332; auto tune 230, 336; pitch 234, 340; and phase 238, 344 (shown in FIGS. 3 and 4). The voice modification may include additional desired effects in other embodiments as would be known by an ordinary person skilled in the art now or in the future.

Distortion, 218, 324 includes modifying the voice signal 216, 320 waveform by clipping the signal. Clipping includes limiting a signal once it exceeds a threshold. Clipping may be hard, in embodiments where the signal is strictly limited at the threshold, producing a flat cutoff. Hard clipping may result in many high frequency harmonics. Clipping may be soft, in embodiments where the clipped signal continues to follow the original at a reduced gain. Soft clipping may result in fewer higher order harmonics. In some embodiments the type and amplitude of distortion 218 may be selected through the user interface 108. Distortion 218, 324 is well known by ordinary persons skilled in the art.

Delay 222, 328 sometimes referred to as echo, may include creating a copy of the voice signal 216, 320 and slightly time-delaying the copied signal creating a “slap”. In another embodiment the copied signal may be repeated at different delayed times creating an echo effect with the multiple repetitions. The number of times the copied signal is repeated may be set or the user may be able to adjust or set this. Delay 222, 328 is well known by ordinary persons skilled in the art.

Reverb 226, 332, sometimes referred to as reverberation, is the effect of persistence of a sound in a particular space after the original sound is removed. Reverberation may be created when a sound is produced in an enclosed space causing a large number of echoes to build up and then slowly decay as the sound is absorbed by the walls and air. This is most noticeable when the sound source stops but the reflections continue, decreasing in amplitude, until they can no longer be heard. Reverb 226, 332 voice signal modification may seek to create the same effect by digital signal processing of a sound signal. Various signal processing algorithms are known by ordinary persons skilled in the art to create the reverb effect. Since reverberation is essentially caused by a very large number of echoes, simple reverberation algorithms may use multiple feedback delay circuits to create a large, decaying series of echoes. More advanced digital reverb algorithms may simulate the time and frequency domain responses of real rooms (based upon room dimensions, absorption and other properties). Any reverberation algorithm known by an ordinary person skilled in the art now or in the future may be used to modify the voice signal 216, 320, to create a desired voice signal 248, 354. The type of reverberation algorithm used may be set or the user may be able to adjust it using the user interface 108. Reverb 226, 332 is well known by ordinary persons skilled in the art.

Autotune 230, 336 may include modifying the voice signal 216, 320 using pitch correction technologies to disguise inaccuracies and mistakes in vocal and instrumental performances. Many different embodiments of autotune 230, 336, as known by an ordinary person skilled in the art now or in the future, are contemplated to be incorporated into the microphone 100. For example, in one embodiment autotune 230, 336 includes Auto-Tune, proprietary audio processing algorithms, techniques, and methods created by Antares Audio Technologies, that use a phase vocoder to correct pitch in vocal and instrumental performances. Autotune 230, 336 is well known by ordinary persons skilled in the art.

Pitch 234, 340 (sometimes referred to as transposing) may include modifying the voice signal 216, 320 to create a desired voice signal 248, 354 by transposing the frequency up or down an interval, while keeping the tempo the same. For example, the frequency of each note of the voice signal 216, 320 may be raised or lowered by a perfect fifth. Techniques used to create the pitch 234, 340 modification may include transposing the voice signal 216, 320 while holding speed or duration constant. In one embodiment this may be accomplished by time stretching and then re-sampling back to the original length. In another embodiment, the frequency of the sinusoids in a sinusoidal model may be altered directly, and the signal reconstructed at the appropriate time scale. The interval to raise or lower the pitch of the voice signal 248, 354 may be set, or a user may choose or adjust the interval using the user interface 108. Pitch 234, 340 is well known by ordinary persons skilled in the art.

Phase 238, 344, (sometimes referred to as phase shifting) may include creating a complex frequency response containing many regularly-spaced notches by combining the voice signal 216, 320 with a copy of itself out of phase, and shifting the phase relationship cyclically to create the desired voice signal 248, 354. The phasing effect has been described by some as creating a “whooshing” sound that is reminiscent of the sound of a flying jet. The angle of the copy is out of phase with the voice signal 216, 320, and the length of cycles may be set in some embodiments. In other embodiments the user may be able to make adjustments or selections or phase 238, 344 using the user interface 108. Phase 238, 344 is well known by ordinary persons skilled in the art.

The user interface 108 in the depicted embodiment includes user input devices 110. User input devices 110 allow the user of the microphone 100 to select at least one voice modification to be made to the voice signal 216, 320. In the depicted embodiment the user input devices include six (6) push buttons 118. The push buttons 118 are spring loaded and biased in a protruding position. When depressed, a push button 118 may activate a switch (not shown) which generates a signal indicating that the user desires the voice signal 216, 320 be modified in a selected manner. The push button 118 then springs back into the protruding position. When a push button 118 is depressed a second time the switch may be activated in different state and a signal generated indicating that the user no longer wishes the voice signal 216, 320 be modified in a selected manner.

In other embodiments the user input devices 110 may include one or more of toggle switches, sliding switches, knobs, keypads, dials, touchscreens, swivel switches, joysticks and touchpads. The user input devices 110 may include any device that would be known by an ordinary person skilled in the art now or in the future that could be used by a user of the microphone 100 to select a desired modification for the voice signal 216, 320.

The user interface 108 may include a display 112. The display 112 indicates to the user of the microphone 100 which modifications to the voice signal 216, 320 the user has selected. In the depicted embodiment the display 112 includes six (6) LEDs 114A-E corresponding to the six (6) push buttons 110A-E. LEDs 114A-E may include semiconductor diodes that emit light when voltages are applied to them. The LEDs 126 may include forward biased p-n junctions that emit light through spontaneous emission by electroluminescence.

When the user selects a voice modification through depressing a push button 118, the corresponding LED 114 lights. When the user depresses the push button 118 again deselecting the voice modification, the corresponding LED 114 goes dark. In one embodiment, the LEDs 114A-E may produce different colors of light. A different color LED 114 may correspond with each different voice modification available.

In alternative embodiments the display 112 may include electronic display screens such as liquid crystal displays or LED display screens, or any output device for presentation of information on user voice modification selections for visual or tactile reception. In some embodiments the user interface 108 will not include a display 112. Some embodiments of the microphone 100 which do not include a display 112 on the user interface 108 may generate signals that may be transmitted and displayed remotely but in site of the user when the user is performing. Thus, by looking at the remote display the user is able to discern what voice modifications he/she has selected.

The user interface 108 may include labels 116A-E, which correspond to the user input devices 110A-E, to identify which modification is selected. In the embodiment depicted, the labels 116 include abbreviations of the voice modification. In other embodiments the labels 116 may include pictures or symbols to identify the voice modification identified with the user input device 110. The labels 116 may include laminates, etchings, moldings, or painted words or symbols. On user interfaces with touchpads or touchscreens the labels 116 may be words, abbreviations, pictures, or symbols on the touchpads or touchscreens. The labels 116 may include any item, symbol, picture, word, or abbreviation which would identify to the user a voice modification that a user input device 110 is associated with.

The microphone 100 may include a cable 128 through which signals may be transmitted to any sound system 204, 304 (described in relation to FIGS. 3 and 4) component located remotely from the microphone 100. In other embodiments the microphone 100 may not include a cable 100 and will include circuitry and programming logic to transmit wireless signals to any sound system 204, 304 component located remotely from the microphone 100.

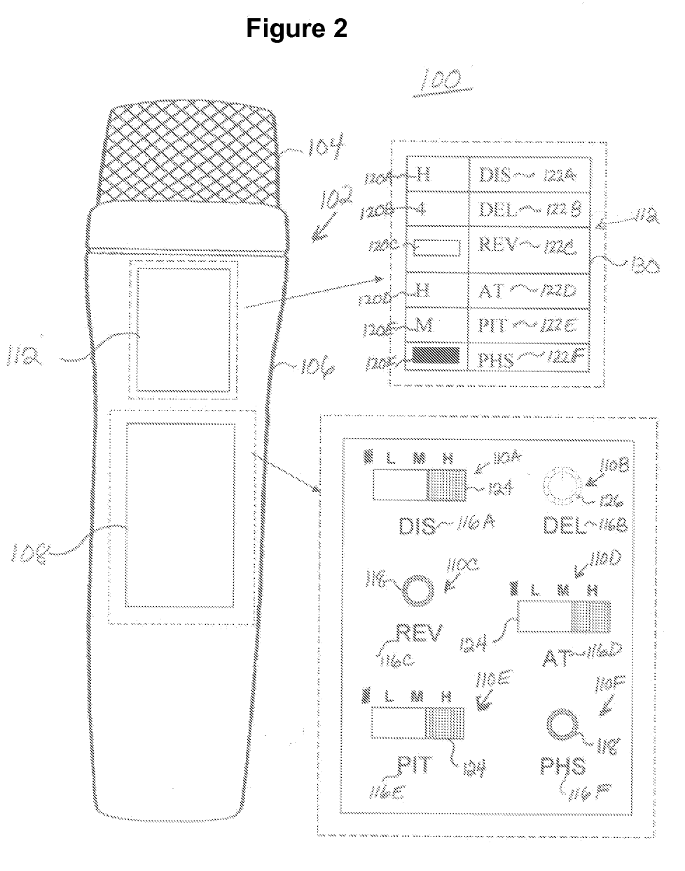

With reference to FIG. 2, an exemplary embodiment of a microphone 100 is depicted. In the embodiment depicted the microphone 100 includes a housing 102. The housing 102 includes a reception portion 104 and a handle portion 106. The reception portion 104 channels sound waves to an audio to electrical converter 206. The handle portion 106 is adapted to be held in a human hand.

A user interface 108 is attached to the housing 102. The user interface 108 allows the user of the microphone 100 to select at least one voice modification they desire. When a voice modification is selected, the voice signal 216, 320 is modified to create a desired voice signal 248, 354. When the desired voice signal 248, 354 is amplified and transformed into sound waves, the listener hears a voice with the user's desired modification.

The user interface 108 is configured to allow selection of a voice modification including at least one of distortion 218, 324; delay 222, 328; reverb 226, 332; auto tune 230, 336; pitch 234, 340; and phase 238, 344. The voice modification may include additional desired effects in other embodiments as would be known by an ordinary person skilled in the art now or in the future.

The user interface 108 in the depicted embodiment includes user input devices 110. User input devices 110 allow the user of the microphone 100 to select at least one voice modification to be made to the voice signal 216, 320. In the depicted embodiment the user input devices include two (2) push buttons 118, three (3) sliding four-way sliding switches 124, and one (1) dial 126.

Four-way sliding switches 124 are well-known by ordinary persons skilled in the art. A user may select the level of a voice modification by sliding the switch 124 to different positions. For example, the user input device 110A includes a switch 124 controlling distortion 218, 324. The user may choose no distortion 218, 324 by moving the switch 124 to a first position labeled with a black rectangle. The user may choose a low level of distortion 218, 324 by sliding the switch 124 to a second position labeled “L”. The user may choose a medium level of distortion 218, 324 by sliding the switch 124 to a third position labeled “M”. The user may choose a high level of distortion by sliding the switch 124 to a fourth position labeled “H”. User input device 110D for Autotune 230, 336, and user input device 110E for Pitch 234, 340 include similar four-way switches 124 which operate in similar ways.

Dials 126 are well-known by ordinary persons skilled in the art. By rotating the dial 126 clockwise the level of Delay 222, 328 may be increased by a user. By rotating the dial 126 counter-clockwise the level of Delay 222, 328 may be decreased by a user. Increasing the level of Delay 222, 328 may increase the number of repeated voice signals or echoes added. Decreasing the level of Delay 222, 328 may decrease the number of repeated voice signals or echoes added. For example, a dial 126 may allow a user to select a level of Delay 222, 328 on a scale from one to ten. The dial 126 would then be marked with numerals or other symbols which would indicate to the user what level of Delay 222, 328 they had selected.

Only one level of voice modification may be selected by a user in the depicted embodiment for Reverberation 226, 332 and Phase 238, 344. User input device 110C includes a push button 118 to activate Reverberation 226, 332. User input device 110F includes a push button 118 to activate Phase 238, 344.

The user interface includes labels 116A-F which identify to a user voice modification selections corresponding to user input devices 110A-F.

The user interface 108 depicted includes a display 112. The display 112 indicates to the user of the microphone 100 which modifications to the voice signal 216, 320 the user has selected and may display the level at which the user has selected the voice modification. In the depicted embodiment, the display 112 includes a screen display 130. The screen display 130 may include a liquid crystal display or an LED screen display. The screen display 130 may include any surface known by an ordinary person in the art now or in the future on which an electronic image is displayed, providing information to a user relating to voice modifications selected and/or the level of voice modifications selected.

The screen display 130 depicted includes images of abbreviations 122A-F of the available voice modifications and the levels 120A-F that have been selected for each voice modification. In the depicted embodiment, the display screen 130 indicates that Distortion 218, 324 has been selected at a high level; Delay 222, 328 has been selected at a level “4”; Reverberation 226, 332 has been selected; Autotune 230, 336 has been selected at a high level; Pitch 234, 340 has been selected at a medium level; and Phase 238, 344 has not been selected.

The microphone 100 in the depicted embodiment does not include a cable and may be configured to send and receive wireless signals.

Referring now to FIG. 3, an exemplary block diagram of a sound system 200 is depicted. The sound system 200 includes a microphone 202 and exterior components 204. The microphone 202 includes an A to E converter 206. When a person 256 speaks or sings into the microphone 202, sound waves 258 are created. The sound waves enter the microphone 202 and the A to E converter 206 converts the sound waves to an analogous electrical signal.

The A to E converter 206 may include any device, circuit, or combination of devices and/or circuits which transforms the mechanical energy of sound waves into an analogous electrical signal known to an ordinary person skilled in the art now or in the future. The A to E converter 206 may, for example, include an electrical circuit with a thin metal or plastic diaphragm with carbon dust on one side. When the carbon dust is compressed by sound waves it's electrical resistance changes, producing an electrical signal analogous to the sound waves. In another embodiment, the A to E converter 206 may include a capacitor. One of the plates of the capacitor includes a diaphragm which moves when exposed to sound waves changing the capacitance of the capacitor and creating an electrical signal analogous to the sound waves. Other types of A to E converters 206 include a thin ribbon suspended in a magnetic field. When sound waves move the ribbon, the current passing through the ribbon changes producing an electrical signal analogous to the sound waves. Another A to E converter 206 may include a crystal attached to a diaphragm. Another embodiment of the A to E converter 206 may include a magnet attached to a diaphragm. The A to E converter 206 generates an electrical voice signal 208, analogous to sound waves 258.

The microphone 202 includes a signal conditioner 210 in the depicted embodiment. When a user sings or speaks into a microphone they may want a clear signal created of their voice devoid of other background sounds. In addition to the sound waves entering the microphone 202, other mechanical energy from the environment may also enter. During transformation of the mechanical energy of sound waves and other sources, an electrical signal may be subject to changes from other sources. The background sounds, additional mechanical energy from the environment, and changes in the electrical signal from other sources may create unwanted noise. If the electrical signal continues to contain the noise, the sound that eventually is broadcast from speakers may contain undesired static or other noises. The signal conditioner 210 may include any device, circuit, or combination of devices and/or circuits which filters unwanted noise from the electrical voice signal 208.

In some embodiments the signal conditioner 210 may convert the electrical voice signal 208 into a plurality of electrical signals, each representing a particular bandwidth of the electrical voice signal 208. For example, the signal conditioner 210 may convert the electrical voice signal 208 into four signals, the first with a band width suitable for a sub-woofer speaker, the second with a band width suitable for a woofer speaker, the third with a band width suitable for a medium speaker, and the fourth with a band width suitable for a tweeter speaker. In the description that follows, the signals generated will be referred to in the singular. In some embodiments, the singular signal may include a plurality of signals each representing a particular bandwidth. The signal conditioner 210 generates a filtered voice signal 212.

The microphone 202 in the embodiment depicted includes analogue to digital converter 214, hereafter referred to as an “ADC”. The ADC 214 may include any device, circuit, or combination of devices and/or circuits which converts continuous electrical signals to a discrete digital number signal known to an ordinary person skilled in the art now or in the future. In the depicted embodiment, the ADC includes an electronic device that converts the filtered voice signal 212 into a digital voice signal 216.

As described in relation to FIGS. 1 and 2, the microphone 202 includes a user interface 108. The user interface 108 may allow the user to select voice modifications and levels of voice modifications for Distortion 218, Delay 222, Reverberation 226, Autotune 230, Pitch 234, and Phase 238. The user interface 108 is configured to generate a modification signal(s) 220, 224, 228, 232, 236, 240 indicative of the selection(s). When a user selects a Distortion 218 voice modification the user interface generates a distortion signal 220 indicative of the selection and any level selected. When a user selects a Delay 222 voice modification the user interface generates a delay signal 224 indicative of the selection and any level selected. When a user selects a Reverberation 226 voice modification the user interface generates a reverb signal 228 indicative of the selection and any level selected. When a user selects an Autotune 230 voice modification the user interface generates an autotune signal 232 indicative of the selection and any level selected. When a user selects a Pitch 234 voice modification the user interface generates a pitch signal 236 indicative of the selection and any level selected. When a user selects a Phase 238 voice modification the user interface generates a phase signal 240 indicative of the selection and any level selected.

The embodiment of the microphone 202 depicted, includes a control module 212 configured to generate a desired voice signal 248 indicative of a desired sound as a function of the modification signal(s) and the digital voice signal 216. The control module 212 may include a processor 242, memory component 244, and signal generator 246. The processor 242 may include a microprocessor, a digital signal processor (DSP), or any processor known to an ordinary person skilled in the art now or in the future. The memory component 244 may store programs, methods, processes, algorithms, and other data that may be utilized by the processor 242 to modify the digital voice signal 216 with the modifications selected on the user interface 108. The processor may implement programs, methods, processes, and algorithms to modify the digital voice signal and generate a signal indicative of a desired voice signal 248. The signal generator 246 may be operable to generate and transmit a desired voice signal 248 to external components 204 of the sound system 200.

The desired voice signal 248 may be in analogue or digital form. Generally, digital signals will transmit with fewer errors than analogue. However, if the external components 204 are configured to accept only analogue signals the signal generator 246 may convert a digital signal to analogue and then transmit it to external components 204 via a physical cable 128.

In the depicted embodiment, the external components 204 include an amplifier component 250 and a speaker component 254. The amplifier component 250 may include any device that increases the amplitude of the desired voice signal 248 known to an ordinary person skilled in the art now or in the future. The amplifier component 250 may use digital or analogue technology.

The amplifier component 250 generates an amplified desired voice signal 252. The amplifier voice signal 252 may be digital or analogue.

The speaker component 254 may include any electroacoustic transducer that converts an electrical signal into sound known by an ordinary person skilled in the art now or in the future. The speaker component 254 may include at least one element which pulses in accordance with the variations of an electrical signal and causes sound waves to propagate through a medium such as air. In the depicted embodiment, the speaker component 254 converts the amplified desired voice signal 252 into sound waves. A listener then may hear the voice of the user singing or speaking with the modification that the user selected on the user interface 108.

Referring now to FIG. 4, an exemplary block diagram of a sound system 300 is depicted. The depicted sound system 300 includes a microphone 302 and exterior components 304. The microphone 302 includes an A to E converter 310. When a person 306 sings or speaks into the microphone 302, sound waves 308 are created. The A to E converter 310 converts the sound waves 308 into an electrical voice signal 312 analogous to the sound waves 308.

The microphone 302 depicted includes a signal conditioner 314. The signal conditioner 314 filters noise from the electrical voice signal 312 and may convert the electrical voice signal 312 into a plurality of signals. Each of the plurality of signals is representative of a particular bandwidth of the electrical voice signal 312. The signal conditioner 314 depicted generates a filtered voice signal 316.

The microphone 302 depicted includes an ADC 318. The ADC 318 converts the filtered voice signal 316 from an analogue signal to a digital voice signal 320.

As described in relation to FIGS. 1 and 2, the microphone 302 includes a user interface 108. The user interface 108 may allow the user to select voice modifications and levels of voice modifications for Distortion 324, Delay 328, Reverberation 332, Autotune 336, Pitch 340, and Phase 344. The user interface 108 is configured to generate a modification signal(s) 326, 330, 334, 338, 342, 346 indicative of the selection(s). When a user selects a Distortion 324 voice modification the user interface generates a distortion signal 326 indicative of the selection and any level selected. When a user selects a Delay 328 voice modification the user interface generates a delay signal 330 indicative of the selection and any level selected. When a user selects a Reverberation 332 voice modification the user interface generates a reverb signal 334 indicative of the selection and any level selected. When a user selects an Autotune 336 voice modification, the user interface generates an autotune signal 338 indicative of the selection and any level selected. When a user selects a Pitch 340 voice modification the user interface generates a pitch signal 342 indicative of the selection and any level selected. When a user selects a Phase 344 voice modification the user interface generates a phase signal 346 indicative of the selection and any level selected.

The depicted embodiment of the microphone 302 includes a signal generator 322. The signal generator 322 may be configured to generate and transmit to the external components 304 a signal indicative of the digital voice signal 320 and the voice modifications the user has selected on the user interface 108.

In the depicted embodiment the external components 304 include a control module 348, an amplifier component 356 and a speaker component 360. The control module 348 may be configured to generate a desired voice signal 354 indicative of a desired sound as a function of the modification signal(s) and the digital voice signal 320. The control module 348 may include a processor 350 and a memory component 352. The processor 350 may include a microprocessor, a digital signal processor (DSP), or any processor known to an ordinary person skilled in the art now or in the future. The memory component 352 may store programs, methods, processes, algorithms, and other data that may be utilized by the processor 350 to modify the digital voice signal 320 with the modifications selected on the user interface 108. The processor may implement programs, methods, processes, and algorithms to modify the digital voice signal 320 and generate a desired voice signal 354.

The amplifier component 356 generates an amplified desired voice signal 358. The amplifier voice signal 358 may be digital or analogue. The speaker component 360 converts the amplified desired voice signal 358 into sound waves. A listener then may hear the voice of the user singing or speaking with the modification that the user selected on the user interface 108.

Other aspects, objects and features of the present invention can be obtained from a study of the drawings, the disclosure, and the appended claims.

What is claimed is:

1. A microphone, comprising:
a housing;
a user interface attached to the housing, configured to allow selection of a voice modification including at least one of distortion, delay, reverb, auto tune, pitch, and phase; and generate a modification signal indicative of the selection;
an audio to electric signal converter at least partially enclosed in the housing, configured to convert sound waves into an electric voice signal;
a control module configured to generate a signal indicative of a desired sound as a function of the modification signal and the electric voice signal.

2. The microphone of claim 1, wherein the user interface includes at least one user input device configured to select the voice modification.

3. The microphone of claim 2, wherein the at least one user input device includes a push button.

4. The microphone of claim 1, wherein the user interface includes a display configured to indicate the voice modification selected.

5. The microphone of claim 4, wherein the display includes at least one LED.

6. The microphone of claim 4, wherein the display includes a display screen.

7. The microphone of claim 1, wherein the user interface is configured to allow selection of a voice modification including a level of at least one of distortion, delay, reverb, auto tune, pitch, and phase.

8. The microphone of claim 1, further comprising a cable configured to transmit the signal indicative of a desired sound to an external sound system component.

9. The microphone of claim 1, wherein the control module is configured to transmit the signal indicative of a desired sound in a wireless manner to an external system component.

10. An audio signal processing method, comprising:
converting sound vibrations into an electrical voice signal;
selecting a voice modification, including at least one of distortion, delay, reverb, auto tune, pitch, and phase, on a user interface of a microphone;
generating a modification signal indicative of the voice modification; and
generating a desired sound signal as a function of the electric voice signal and the modification signal.

11. The audio signal processing method of claim 10, further comprising:
converting sound vibrations into an analogue electrical voice signal;
converting the analogue electrical voice signal into a digital voice signal; and
generating a desired sound signal as a function of the digital voice signal and the modification signal.

12. The audio signal processing method of claim 10, wherein the voice modification includes distortion.

13. The audio signal processing method of claim 10, wherein the voice modification includes delay.

14. The audio signal processing method of claim 10, wherein the voice modification includes reverberation.

15. The audio signal processing method of claim 10, wherein the voice modification includes autotune.

16. The audio signal processing method of claim 10, wherein the voice modification includes pitch.

17. The audio signal processing method of claim 10, wherein the voice modification includes phase.

18. The audio signal processing method of claim 10, further comprising transmitting the desired sound signal to an amplifier.

19. The audio signal processing method of claim 18, further comprising amplifying the desired sound signal to generate an amplified desired sound signal.

20. The audio signal processing method of claim 19, further comprising converting the amplified desired sound signal to sound waves.
